(19) United States
(12) Patent Application Publication
(10) Pub. No.: US 2010/0065425 A1
(43) Pub. Date: Mar. 18, 2010

(54) SILVER ALLOY SPUTTERING TARGET AND PROCESS FOR PRODUCING THE SAME

(75) Inventors: Hitoshi Matsuzaki, Hyogo (JP); Katsutoshi Takagi, Hyogo (JP); Junichi Nakai, Hyogo (JP); Yasuo Nakane, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KOBELCO RESEARCH INSTITUTE, INC., Hyogo (JP)

(21) Appl. No.: 12/625,022

(22) Filed: Nov. 24, 2009

Related U.S. Application Data
(63) Continuation of application No. 10/486,913, filed on Feb. 23, 2004.

(30) Foreign Application Priority Data
Jun. 24, 2002 (JP) 2002-183462
Jun. 24, 2002 (JP) 2002-183463

(51) Int. Cl. C23C 14/34; C22F 1/14

(52) U.S. Cl. 204/298.13; 148/678

(57) ABSTRACT

A silver alloy sputtering target is provided which is useful in forming a thin silver-alloy film of a uniform thickness by the sputtering method. When crystal orientation strengths are determined at four arbitrary positions by the X-ray diffraction method, the orientation which exhibits the highest crystal orientation strength (Xₐ) is the same at the four measurement positions, and variations in strength ratio (X_{b}/Xₐ) between the highest crystal orientation strength (Xₐ) and the second highest crystal orientation strength (X_{b}) is 20% ore less.

### FIELD OF ART

The present invention relates to a silver alloy sputtering target used in forming a thin film by the sputtering method and more particularly to a silver alloy sputtering target capable of forming a thin film which is uniform in both film thickness and composition.

### BACKGROUND ART

A thin film of pure silver or silver alloy has such characteristics as high reflectivity and low electric resistivity and is therefore applied, for example, to a reflective film in an optical recording medium or to an electrode and an optical reflective film in a reflection type liquid crystal display.

However, a thin film of pure silver, when exposed to air for a long time or exposed to high temperature and high humidity, is apt to be oxidized at its surface and there easily occurs such a phenomenon as the growth of silver crystal grains or aggregation of silver atoms. As a result, there arise problems such as lowering of electric conductivity and reflectivity or deterioration in the adherence of the film to a substrate. Recently, therefore, for improving the corrosion resistance, etc. while maintaining a high reflectivity inherent in pure silver, many attempts have been made to add alloy elements to silver. In parallel with such attempts for the improvement of thin film there also have been made studies about a target used for forming a thin film of silver alloy. For example, in Japanese Published Unexamined Patent Application No. 2001-192752, a sputtering target is shown as one of metallic materials for electronic parts, the sputtering target containing Ag as a main component, also containing 0.1 to 3 wt % of Pd for the improvement of corrosion resistance, and further containing 0.1 to 3 wt % of plural elements selected from the group consisting of Al, Au, Pt, Cu, Ta, Cr, Ti, Ni, Co, and Si to suppress an increase of electric resistivity caused by the addition of Pd.

In Japanese Published Unexamined Patent Application No. Hei 9-324264 there is suggested a silver alloy sputtering target, the silver alloy sputtering target containing 0.1 to 2.5 at % of gold to prevent a bad influence caused by oxygen, etc. present in a gas atmosphere during sputtering and further containing 0.3 to 3 at % of copper to suppress a decrease of light transmittance caused by the addition of gold, or a sputtering target of a composite metal comprising a silver target and both gold and copper embedded in part of the silver target at the aforesaid proportions.

Further, in Japanese Published Unexamined Patent Application No. 2000-239835 there is disclosed a silver or silver alloy sputtering target and it is suggested therein that, for increasing the sputtering yield of target at the time of forming a film by sputtering and thereby carrying out sputtering efficiently, the crystal structure of target be made a face-centered cubic structure and the crystal orientation be set at 2.20 or more in terms of a plane orientation degree ratio of ((111)+(200))/(220).

In the case where a thin film formed by the sputtering method is used as a semi-transmissive reflective film in DVD of a one-side two-layer structure for example, the film thickness is as very small as 100 Å or so and the uniformity in thickness of the thin film exerts a great influence on such characteristics as reflectivity and transmittance, so that importance is attached to forming a thin film having a more uniform thickness. In case of using such a thin film as a reflective film in a next generation optical recording medium, it is required that the heat generated by laser power at the time of recording be transmitted quickly. Therefore, not only excellent optical characteristics are required, but also it is required that the thermal conductivity be uniform and high in plane. To meet this requirement it is required that the thin film be uniform in both thickness and composition.

Thus, when the thin film used as a reflective film or a semi-transmissive reflective film in an optical recording medium is to be formed by the sputtering method, even if the composition of a target and the crystal orientation degree ratio are controlled as in the prior art, it is impossible to surely obtain a thin film uniform in both thickness and composition and able to exhibit high reflectivity and high thermal conductivity required of a reflective film in an optical recording medium. Therefore, it is considered necessary to make a further improvement of the target.

The present invention has been accomplished in view of the above-mentioned circumstances and it is an object of the invention to provide a silver alloy sputtering target which is useful in forming a thin film uniform in both thickness and composition by the sputtering method.

The silver alloy sputtering target according to the present invention is characterized in that when crystal orientation strengths are determined with respect to four arbitrary positions by the X-ray diffraction method, the orientation which exhibits the highest crystal orientation strength (Xₐ) is the same at the four measurement positions, and that variations in strength ratio (X_{b}/Xₐ) between the highest crystal orientation strength (Xₐ) and the second highest crystal orientation strength (X_{b}) at the four measurement positions are 20% or less. It is preferable that the orientation which exhibits the second highest crystal orientation strength (X_{b}) be the same at the four measurement positions.

The “variations in strength ratio (X_{b}/Xₐ) between the highest crystal orientation strength (Xₐ) and the second highest crystal orientation strength (X_{b})” are determined in the following manner. Crystal orientation strengths are determined with respect to four arbitrary positions by the X-ray diffraction method and a mean value, AVE (X_{b}/Xₐ), of strength ratios (X_{b}/Xₐ) between the highest crystal orientation strength (Xₐ) and the second highest crystal orientation strength (X_{b}) at the four measurement positions is determined. Next, there is determined an absolute value of the following expression (1) or (2), assuming that at the four measurement positions a maximum value of (X_{b}/Xₐ) is MAX(X_{b}/Xₐ) and a minimum value of (X_{b}/Xₐ) is MIN(X_{b}/Xₐ). Then, of the absolute values, the larger one is represented in terms of %.

|MAX(X_{b}/Xₐ)−AVE(X_{b}/Xₐ)|/AVE(X_{b}/Xₐ) (1)

|MIN(X_{b}/Xₐ)−AVE(X_{b}/Xₐ)|/AVE(X_{b}/Xₐ) (2)

It is preferable for the silver alloy sputtering target according to the present invention to satisfy the condition that an average crystal grain size should be 100 μm or less and a maximum crystal grain size should be 200 μm or less. The reason is that if this condition is satisfied, thin films formed by using this target have uniform characteristics. Particularly, in the case of a silver alloy sputtering target with silver-alloy compounds present in grain boundaries and/or crystal grains, it is preferable that equivalent area diameters of the compound phases be 30 μm or less on the average and that a maximum value of the equivalent area diameters be 50 μm or less.

The foregoing “average crystal grain size” is determined by the following measuring method. \textcircled{1} In an optical microphotograph of 50× to 100×, plural straight lines are drawn between edges of the microphotograph, as shown in FIG. 1. From the standpoint of determination accuracy it is preferable that the number of straight lines be four or more. The straight lines may be drawn, for example, in such a parallel crosses shape as shown in FIG. 1(a) or in such a radial shape as in FIG. 1(b). \textcircled{2} Next, the number, n, of grain boundaries present on the straight lines is measured. \textcircled{3} Further, an average crystal grain size, d, is determined from the following expression (3) and a mean value is obtained from the values of d of plural straight lines:

d=L/n/m (3)

where d stands for an average crystal grain size determined from one straight line, L stands for the length of one straight line, n stands for the number of grain boundaries on one straight line, and m stands for magnification.

The foregoing “maximum crystal grain size” has been determined by observing five or more arbitrary positions in the visual field of an optical microscope of 50× to 100× and calculating, in terms of a equivalent area diameter, the grain diameter of a maximum crystal within the range of 20 mm² as a total of all visual fields.

The foregoing “average of equivalent area diameters of the silver-alloy compounds present in grain boundaries and/or crystal grains” has been determined by observing five or more arbitrary positions in the visual field of an optical microscope of 100× to 200×, calculating, in terms of equivalent area diameters, such compound phases present within the range of 20 mm² as a total of all visual fields, and determining a mean value thereof. Further, the “maximum value of the equivalent area diameters of the silver-alloy compounds” represents the equivalent area diameter of a maximum compound phase within the aforesaid total range of 20 mm².

The present invention also specifies a method for producing a silver alloy sputtering target which satisfies the crystal orientation described above. The method involves as an essential condition performing cold working or warm working at a working ratio of 30% to 70% and subsequently performing heat treatment under the conditions of a holding temperature of 500° to 600° C. and a holding time of 0.75 to 3 hours. For obtaining a silver alloy sputtering target having a small crystal grain size it is recommended that the above heat treatment be carried out at a holding temperature of 500° to 600° C. and a holding time within the range of the following expression (4):

(−0.005×T+3.5)≦t≦(−0.01×T+8) (4)

where T stands for a holding temperature (° C.) and t stands for a holding time (hour).

### BRIEF DESCRIPTION OF THE DRAWINGS

FIG. 1 illustrates how to determine an average crystal grain size of a target from an optical microphotograph;

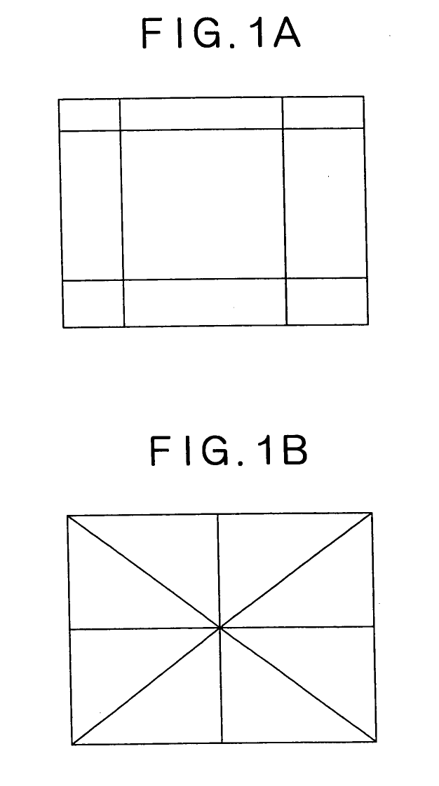

FIG. 2 illustrates the range of heat treatment conditions specified in the present invention;

FIG. 3 illustrates the results of measurement, by the X-ray diffraction method, of crystal orientation strength of a target obtained in Example 1 according to the present invention;

FIG. 4 illustrates the results of measurement, by the X-ray diffraction method, of crystal orientation strength of a target obtained in a comparative example described in Example 1;

FIG. 5 illustrates content distributions (composition distributions) of alloy elements in Ag alloy thin films obtained in Example 1;

FIG. 6 illustrates content distributions (composition distributions) of alloy elements in Ag alloy thin films obtained in Example 2;

FIG. 7 illustrates content distributions (composition distributions) of alloy elements in Ag alloy thin films obtained in Example 3;

FIG. 8 illustrates content distributions (composition distributions) of alloy elements in Ag alloy thin films obtained in Example 5;

FIG. 9 illustrates content distributions (composition distributions) of alloy elements in Ag alloy thin films obtained in Example 6; and

FIG. 10 illustrates alloy element content distributions (composition distributions) in Ag alloy thin films obtained in Example 7.

### BEST MODE FOR CARRYING OUT THE INVENTION

The present inventors have made studies from various standpoints for the purpose of obtaining a silver alloy sputtering target (may be referred to simply as “target” hereinafter) which can afford a thin film uniform in both thickness and composition by sputtering under the above-mentioned circumstances. As a result, we found out that controlling the crystal orientation of the target was particularly effective, and accomplished the present invention on the basis of that finding. The reason why the crystal orientation of the target is specified in the present invention will be described below in detail.

First, in the present invention it is an essential condition that when crystal orientation strengths are determined at four arbitrary positions of the target by the X-ray diffraction method, the orientation which exhibits the highest crystal orientation strength (Xₐ) should be the same at the four measurement positions.

More specifically, in the present invention, the orientation which exhibits the highest crystal orientation strength is not specially defined, but no matter which of (111), (200), (220), and (311) planes may be the orientation exhibiting the highest crystal orientation strength, it is allowable, provided it is necessary that the orientation exhibiting the highest crystal orientation strength be the same at four arbitrary measurement positions. If the orientation which exhibits the highest crystal orientation strength is thus the same at four arbitrary measurement positions, the number of atoms which reach a substrate at the time of sputtering becomes uniform in a substrate plane and thus it is possible to obtain a thin film uniform in thickness.

It is preferable that the orientation which exhibits the highest crystal orientation strength be (111) plane, because it is possible to increase the film-forming speed at the time of sputtering.

Further, it is preferable that variations in strength ratio (X_{b}/Xₐ) between the highest crystal orientation strength (Xₐ) and the second highest crystal orientation strength (X_{b}) be 20% or less at four measurement positions.

This is for the following reason. Even if the orientation which exhibits the highest crystal orientation strength is the same at arbitrary positions, if variations in strength ratio (X_{b}/Xₐ) between the highest crystal orientation strength (Xₐ) and the second highest crystal orientation strength (X_{b}) are too large, the number of atoms reaching a substrate at the time of sputtering is apt to be non-uniform in the substrate plane and thus it is difficult to obtain a thin film having a uniform thickness. It is more preferable that the above variations in strength ratio be 10% or less.

If the above variations are within the specified range at arbitrary positions, the second highest crystal orientation strength (X_{b}) may be different between measurement positions, but it is preferable that the orientation which exhibits the second highest crystal orientation strength (X_{b}) be the same at four measurement positions, because the number of atoms reaching a substrate becomes uniform more easily and there can be easily obtained a thin film uniform in thickness.

If the crystal orientation is thus specified and if the grain diameter of silver crystals and the size of silver-alloy compounds present in grain boundaries and/or crystal grains are controlled, a thin film uniform in both thickness and composition can be formed by sputtering. Thus, this is preferable.

More specifically, it is preferable that an average crystal grain size of the target be set at 100 μm or less and a maximum crystal grain size thereof be set at 200 μm or less.

With the target small in the average crystal grain size, it is possible to easily form a thin film uniform in thickness and eventually possible to improve the performance of an optical recording medium, etc. The above average crystal grain size is preferably 75 μm or less, more preferably 50 μm or less.

Even if the average crystal grain size is 100 μm or less, if crystal grains extremely large in diameter are present, the resulting thin film is apt to be locally non-uniform in thickness. Therefore, for obtaining an optical recording medium whose local deterioration in performance is suppressed, it is preferable that the crystal grain size of a target used in forming a thin film be 200 μm or less even as a maximum, more preferably 150 μm or less, still more preferably 100 μm or less.

If silver-alloy compounds are present in grain boundaries and/or crystal grains of a silver alloy sputtering target, it is preferable to also control the size of the compound phases.

The smaller the size of the compound phases, the more preferable, because the composition of the resulting thin film easily becomes uniform. In the case where the size of the compound phases is represented in terms of a equivalent area diameter, it is preferable that an average thereof be 30 μm or less, more preferably 20 μm or less.

Even if the size of the compound phases is 30 μm or less, if an extremely large compound phase is present, a discharge condition of sputtering is apt to become unstable and it becomes difficult to obtain a thin film which is uniform in composition. Therefore, it is preferable that the maximum compound phase be 50 μm or less, more preferably 30 μm or less, in terms of a equivalent area diameter.

It is not that the present invention specifies even composition of the compound phases. As examples of compound phases to be controlled there are mentioned Ag₅₁Nd₁₄ or Ag₂Nd present in Ag—Nd alloy target, Ag₅₁Y₁₄ or Ag₂Y present in Ag—Y alloy target, and AgTi present in Ag—Ti alloy target.

In order to obtain a target which satisfies the crystal orientation specified above, it is preferable that cold working or warm working be carried out at a working ratio of 30% to 70% in the manufacturing process. With such a cold or warm working, not only it is possible to effect molding substantially up to a product shape, but also a working strain is accumulated and it is possible to attain a uniform crystal orientation by recrystallization in the subsequent heat treatment.

If the working ratio is less than 30%, the amount of strain applied is insufficient, so that, even if heat treatment is performed thereafter, there occurs recrystallization only partially and it is impossible to fully attain a uniform crystal orientation. It is preferable that cold working or warm working be carried out at a working ratio of 35% or more. On the other hand, if the working ratio exceeds 70%, the recrystallization speed in heat treatment becomes too high and also in this case there eventually occur variations in crystal orientation more easily. Preferably, cold or warm working is carried out at a working ratio of 65% or less.

The working ratio means [(the size of material before working−the size of material after working)/the size of material before working]×100 (%) (this also applies to the following). For example, in case of forging or rolling a plate-like material into a plate-like product, the plate thickness may be used as the “size” to calculate the working ratio. In case of producing a plate product with use of a cylindrical material, the working ratio calculating method differs depending on the working method adopted. For example, in case of performing forging or rolling while applying force in the height direction of a cylindrical material, a working ratio can be determined from [(height of the cylindrical material before working−thickness of a plate-like material after working)/height of the cylindrical material before working]×100 (%). In case of performing forging or rolling while applying force radially of a cylindrical material, a working ratio can be determined from [(diameter of the cylindrical material before working−thickness of a plate-like material after working)/diameter of the cylindrical material before working]×100 (%).

The cold working or warm working is followed by heat treatment under the conditions of a holding temperature of 500° to 600° C. and a holding time of 0.75 to 3 hours. With such a heat treatment, it is possible to attain a uniform crystal orientation.

If the holding temperature is lower than 500° C., the time required until recrystallization becomes longer, while if, the holding temperature exceeds 600° C., the recrystallization speed becomes higher, and if there are variations in the amount of material strain, the recrystallization is promoted at a portion where the amount of strain is large, thus making it difficult to attain a uniform crystal orientation, which is not desirable. More preferably, the heat treatment is carried out at a temperature in the range of 520° to 580° C.

Even if the holding temperature is within an appropriate range, if the holding time is too short, recrystallization will not be carried out to a satisfactory extent, while if the holding time is too long, recrystallization will proceed too much, making it difficult to attain a uniform crystal orientation. Therefore, it is preferable that the holding time be set within the range of 0.75 to 3 hours.

For making crystal grains fine, it is preferable to carry out heat treatment under the conditions of a holding temperature of 500° to 600° C. (more preferably 520° to 580° C.) and a holding time in the range of the following expression (4):

(−0.005×T+3.5)≦t≦(−0.01×T+8) (4)

where T stands for the holding temperature (° C.) and t stands for the holding time (hour).

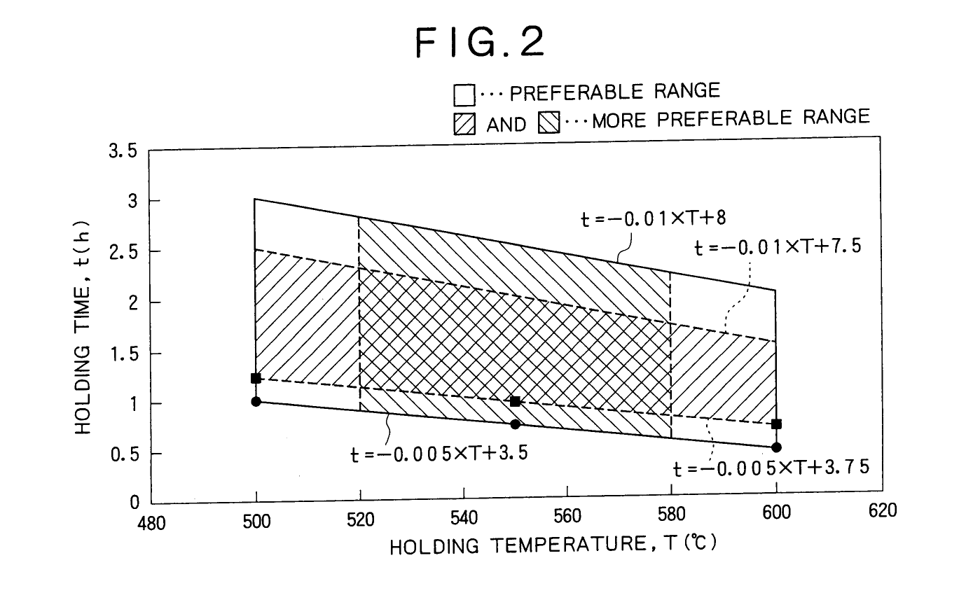

In the range of the above expression (4) it is recommended that the holding time be set within the range specified by the following expression (5). Preferred ranges of the holding time and holding temperature in the heat treatment are shown in FIG. 2.

(−0.005×T+3.75)≦t≦(−0.01×T+7.5) (5)

where T stands for the holding temperature (° C.) and t stands for the holding time (hour).

In the present invention, other conditions associated with target production are not strictly defined, but the target can be obtained, for example, in the following manner. According to one of recommended methods, silver alloy material having a predetermined composition is melted and is subjected to casting to obtain ingot. Thereafter, if necessary, hot working such as hot forging or hot rolling is performed for the ingot. Next, cold working or warm working and heat treatment are performed under the foregoing conditions, followed by machining into a desired shape.

The above melting of the silver alloy material may be done by atmospheric melting in a resistance heating type electric furnace or by induction melting in an inert atmosphere. Molten silver alloy exhibits a high oxygen solubility, so in the case of atmospheric melting referred to above it is necessary, for preventing oxidation to a satisfactory extent, to use a graphite crucible and cover the molten alloy surface with flux. From the standpoint of preventing oxidation, it is preferable that melting be conducted in vacuum or in an inert atmosphere. The foregoing casting method is not specially limited. Not only casting may be done using a die or a graphite mold, but also slow-cooling casting which uses a refractory or a sand mold may be performed on condition that reaction with the silver alloy material does not occur.

Hot working is not essential, but for example in case of making a cylindrical shape into a rectangular parallelepiped or plate-like shape, there may be performed a hot working such as hot forging if necessary. However, it is necessary that the working ratio in hot working be set within such a range as permits ensuring a predetermined working ratio in the subsequent cold or warm working step. This is because if the cold working or warm working is not carried out to a satisfactory extent, recrystallization cannot be done due to insufficient strain and eventually crystal orientation is not rendered uniform. In case of performing a hot working, other conditions are not specially limited, but there may be adopted conventional working temperature and time.

It is desirable that a preliminary experiment be conducted prior to operation to determine optimal working and heat treatment conditions so as to match the kind and amount of alloy element used.

The present invention does not specify a composition of the target, but for obtaining the target described above it is recommended to use the following compositions for example.

As noted above, the target according to the present invention comprises silver as a base material and any of the following elements added thereto. Preferably, one or more of the following alloy elements are added: 1.0 at % (meaning atomic ratio, also in the following) or less of Nd which is effective in making the crystal grain size of the resulting thin film finer and stabilizing the thin film against heat, 1.0 at % or less of a rare earth element (e.g., Y) which exhibits the same effect as Nd, 2.0 at % or less of Au which is effective in improving the corrosion resistance of the resulting thin film, 2.0 at % or less of Cu which, like Au, also exhibits the corrosion resistance improving effect, and other elements such as Ti and Zn. For example, impurities attributable to the materials used in producing the target of the present invention or to the target producing atmosphere may be contained in the target within such a range as does not affect the formation of the crystal structure defined in the present invention.

The target of the present invention is applicable to, for example, any of DC sputtering method, RF sputtering method, magnetron sputtering method, and reactive sputtering method, and is effective in forming a thin silver-alloy film of about 20 to 5000 Å. The shape of the target may be changed in the stage of design as necessary according to the sputtering apparatus used.

### EXAMPLES

The present invention will be described below in more detail by way of working examples thereof, but the invention is not limited by the following working examples, and suitable changes may be made within the scope conforming to the above and following gists of the invention, which are all included in the technical scope of the invention.

### Example 1

Silver alloy material: Ag-1.0 at % Cu-0.7 at % Au

Manufacturing Method:

\textcircled{1} Example of the Present Invention

Induction melting (Ar atmosphere)→casting (into a plate shape with use of a die)→cold rolling (working ratio 50%)→heat treatment (520° C.×2 hours)→machining (a disc shape 200 mm dia. by 6 mm thick)

\textcircled{2} Comparative Example

Induction melting (Ar atmosphere)→casting (into a plate shape with use of a mold)→hot rolling (rolling start temperature 700° C., working ratio 70%)→heat treatment (500° C.×1 hour)→machining (a disc shape 200 mm dia. by 6 mm thick)

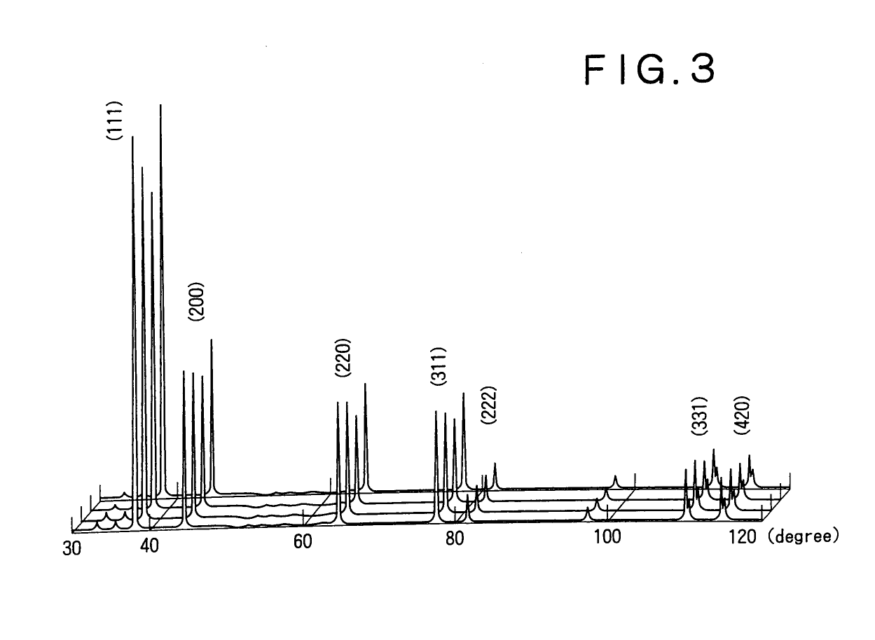

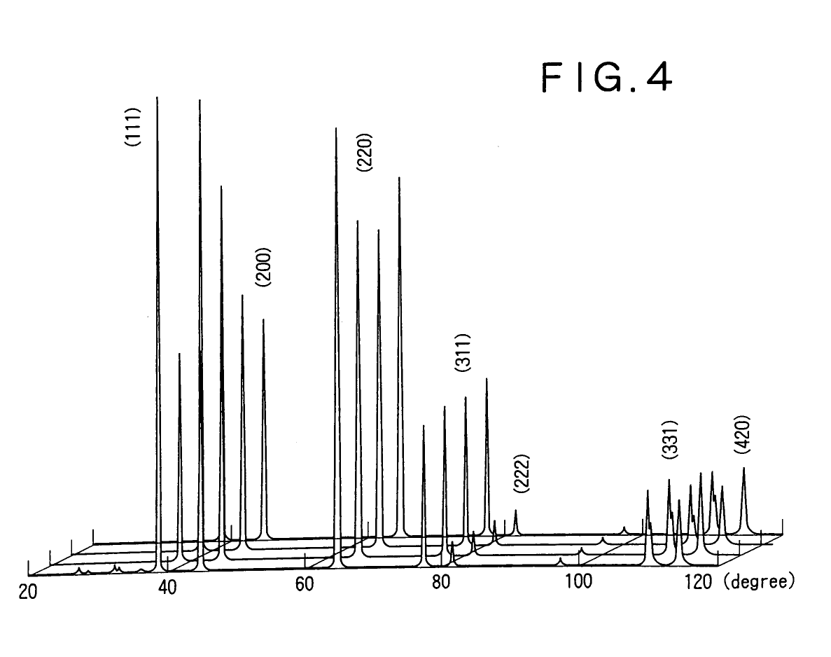

The resulting targets were each checked for crystal orientation strength in the following manner. The surface of each target was subjected to X-ray diffraction at four arbitrary positions under the following conditions and crystal orientation strength was checked. In the Example of the present invention there was obtained such a measurement result as shown in FIG. 3, while in the Comparative Example there was obtained such a measurement result as shown in FIG. 4. From these measurement results there were determined orientation exhibiting the highest crystal orientation strength (Xₐ) and orientation exhibiting the second highest crystal orientation strength (X_{b}). Further, in the same manner as above, variations in strength ratio (X_{b}/Xₐ) between the highest crystal orientation strength (Xₐ) and the second highest crystal orientation strength (X_{b}) were determined at the four measurement positions. In the case where the orientation exhibiting the highest crystal orientation strength (Xₐ) is different at the four measurement positions, the above variations are not determined (this is also the case with the examples which follow).

| | |
|---|---|
| X-ray Diffractometer: | RINT 1500, a product of Rigaku |
| | Denki Co. |
| Target: | Cu |
| Line voltage: | 50 kV |
| Line current: | 200 mA |
| Scanning speed: | 4°/min |
| Sample rotation: | 100 r.p.m. |

The targets were also checked for metal structure in the following manner. A cubic sample of 10 mm×10 mm×10 mm was obtained from each of the targets after machining and an observation surface thereof was polished, then the sample was observed through an optical microscope magnifying 50 to 100 diameters and photographed, then was determined for average crystal grain size and maximum crystal grain size in the manner described above. In the above microscopic observation, polarization was performed as necessary in the optical microscope so that crystal grains could be observed easily. The results obtained are shown in Table 1.

Next, using the targets thus obtained, thin films having an average thickness of 1000 Å were formed on a glass substrate having a diameter of 12 cm by a DC magnetron sputtering method [Ar gas pressure: 0.267 Pa (2 mTorr), sputter power: 1000 W, substrate temperature: room temperature]. Then, with respect to each of the thin films, film thickness was measured successively at five positions from an end of an arbitrary central line. The results obtained are shown in Table 1 (“Distance from substrate end”).

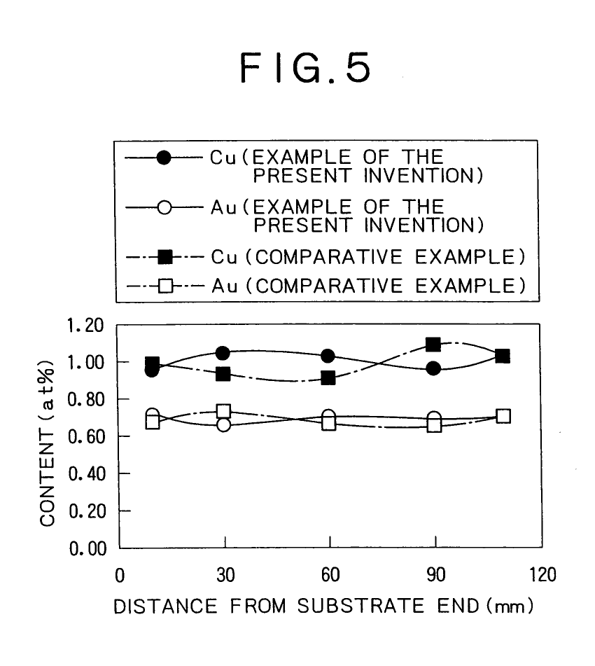

Further, with respect to each of the thin films, content distributions of alloy elements were determined successively from an end of an arbitrary central line of a disc-like thin film-forming substrate by an X-ray microanalysis method (EPMA). There were obtained such results as shown in FIG. 5.

TABLE 1

| | | Orientation | | | | | | | | |
|---|---|---|---|---|---|---|---|---|---|---|
| | | exhibiting the | | | | | | | | |
| | Orientation | second | Variations in | | | | | | | |
| | exhibiting the | highest | crystal | Crystal | | | | | | |
| | highest crystal | crystal | orientation | Grain Size | | Film Thickness Distribution (Å) | | | | |
| | orientation | orientation | strength ratio | Average | Max. | Distance from substrate end (mm) | | | | |
| | strength | strength | (%) | μm | μm | 10 | 30 | 60 | 90 | 110 |
| Example of | (111) at all the | (110) at all the | 10 | 51 | 104 | 990 | 1050 | 1000 | 1020 | 980 |
| the present | four positions | four positions | | | | | | | | |
| invention | | | | | | | | | | |
| Comparative | (111) at two | (220) at two | — | 120 | 297 | 960 | 1120 | 890 | 900 | 1060 |
| Example | positions | positions | | | | | | | | |
| | (220) at two | (111) at two | | | | | | | | |
| | positions | positions | | | | | | | | |

From the above results it is seen that if sputtering is performed using a target which satisfies the conditions defined in the present invention, there is obtained a thin silver-alloy film which is uniform in thickness distribution and which can exhibit stable characteristics. In the case of the targets of the above compositions, FIG. 5 shows that there is little difference in composition distribution between the Example of the present invention and the Comparative Example.

### Example 2

Silver alloy material: Ag-0.8 at % Y-1.0 at % Au

Manufacturing Method:

\textcircled{1} Example of the Present Invention

Vacuum induction melting→casting (produce a cylindrical ingot with use of a mold)→hot forging (produce a slab at 700° C., working ratio 30%)→cold rolling (working ratio 50%)→heat treatment (550° C.×1.5 hours)→machining (into the same shape as in Example 1)

\textcircled{2} Comparative Example

Vacuum induction melting→casting (produce a cylindrical ingot with use of a mold)→hot forging (produce a slab at 650° C., working ratio 60%)→heat treatment (400° C.×1 hour)→machining (into the same shape as in Example 1)

The resulting targets were each checked for crystal orientation strength in the following manner and there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}) at the measurement positions.

The targets were also checked for metal structure in the same way as in Example 1. In the silver alloy material used herein, silver-alloy compounds are present in grain boundaries and crystal grains, and the size of the compound phases was checked in the following manner.

An observation surface of a sample similar to that used in the measurement of the crystal grain size was polished and was then subjected to a suitable etching with use of nitric acid for example in order to clarify the profile of compound, thereafter, as described above, the sample was observed at five or more arbitrary positions through an optical microscope magnifying 100 to 200 diameters, then equivalent area diameters of compound phases present within the range of a total of 20 mm² in all visual fields and a mean value thereof was determined. Also determined was a equivalent area diameter of the maximum compound phase in the total visual field.

In the case where it is difficult to recognize the compound phase, the above optical microscopic observation may be substituted by face analysis (mapping) using EPMA and a mean value and a maximum value of the compound phase sizes may be determined by the conventional image analysis method. The results obtained are shown in Table 2.

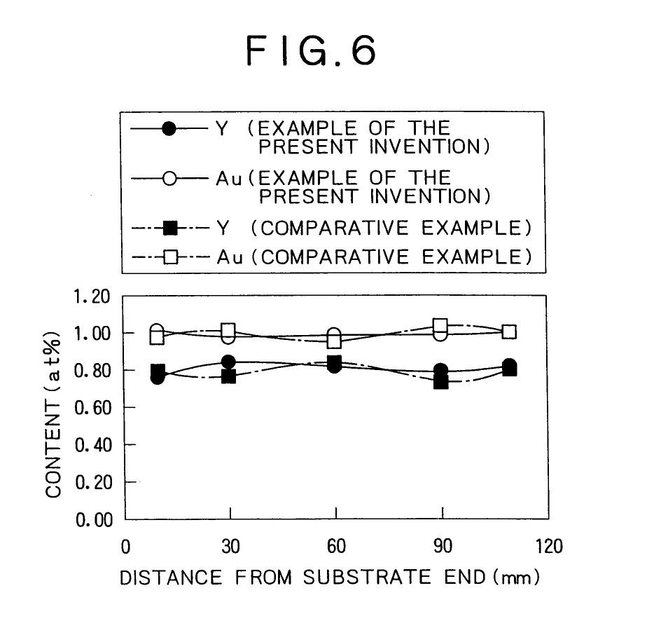

Next, using the targets and in the same way as in Example 1 thin films were formed and then checked for thickness distribution and composition distribution. Thickness distributions and composition distributions of the thin films are shown in Table 2 and FIG. 6, respectively.

TABLE 2

| | | Orientation | | | | | | | | | | |
|---|---|---|---|---|---|---|---|---|---|---|---|---|
| | Orientation | exhibiting | Variations in | | | | | | | | | |
| | exhibiting | the second | crystal | | | | | | | | | |
| | the highest | highest | orientation | Crystal Grain | | | | | | | | |
| | crystal | crystal | strength | Size | | Compounds | | Film Thickness Distribution (Å) | | | | |
| | orientation | orientation | ratio | Average | Max. | Average | Max. | Distance from substrate end (mm) | | | | |
| | strength | strength | (%) | μm | μm | μm | μm | 10 | 30 | 60 | 90 | 110 |
| Example | (111) at all | (110) at all | 11 | 44 | 92 | 37 | 68 | 995 | 1040 | 995 | 1015 | 985 |
| of the | the four | the four | | | | | | | | | | |
| present | positions | positions | | | | | | | | | | |
| invention | | | | | | | | | | | | |
| Comparative | (220) at all | (111) at all | 28 | 115 | 266 | 35 | 59 | 965 | 1110 | 885 | 905 | 1065 |
| Example | the four | the four | | | | | | | | | | |
| | positions | positions | | | | | | | | | | |

From these results it is seen that by sputtering a target which satisfies the conditions specified in the present invention there can be obtained a thin silver-alloy film having a uniform thickness distribution and capable of exhibiting stable characteristics. Reference to FIG. 6 shows that if the crystal grain size of a target is set within the range preferred in the present invention, there can be formed a thin film more uniform in composition distribution.

### Example 3

Silver alloy material: Ag-0.4 at % Nd-0.5 at % Cu

Manufacturing Method:

\textcircled{1} Example of the Present Invention

Vacuum induction melting→casting (produce a cylindrical ingot with use of a mold)→hot forging (produce a slab at 700° C., working ratio 35%)→cold rolling (working ratio 50%)→heat treatment (550° C.×1 hour)→machining (into the same shape as in Example 1)

\textcircled{1} Comparative Example

Vacuum induction melting→casting (produce a cylindrical ingot with use of a mold)→heat treatment (500° C.×1 hour)→machining (into the same shape as in Example 1)

The resulting targets were each checked for crystal orientation strength in the same way as in Example 1 and there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}) at the measurement positions. The results obtained are shown in Table 3.

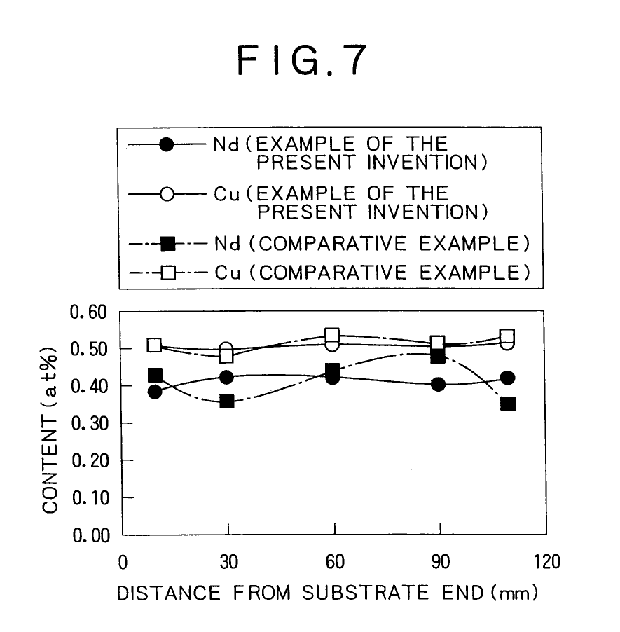

Further, using the targets and in the same way as in Example 1 thin films were formed and checked for thickness distribution and composition distribution. Thickness distributions and composition distributions of the thin films are shown in Table 3 and FIG. 7, respectively.

TABLE 3

| | | Orientation | | | | | | | | | | |
|---|---|---|---|---|---|---|---|---|---|---|---|---|
| | Orientation | exhibiting | Variations | | | | | | | | | |
| | exhibiting | the second | in crystal | | | | | | | | | |
| | the highest | highest | orientation | Crystal Grain | | | | | | | | |
| | crystal | crystal | strength | Size | | Compounds | | Film Thickness Distribution (Å) | | | | |
| | orientation | orientation | ratio | Average | Max. | Average | Max. | Distance from substrate end (mm) | | | | |
| | strength | strength | (%) | μm | μm | μm | μm | 10 | 30 | 60 | 90 | 110 |
| Example of | (111) at all | (110) at all | 11 | 64 | 119 | 32 | 53 | 990 | 1030 | 990 | 1010 | 990 |
| the present | the four | the four | | | | | | | | | | |
| invention | positions | positions | | | | | | | | | | |
| Comparative | (111) at | (220) at | — | 211 | 565 | 76 | 147 | 970 | 1100 | 880 | 910 | 1070 |
| Example | two | two | | | | | | | | | | |
| | positions | positions | | | | | | | | | | |
| | (220) at | (111) at | | | | | | | | | | |
| | two | two | | | | | | | | | | |
| | positions | positions | | | | | | | | | | |

From these results it is seen that by sputtering a target which satisfies the conditions defined in the present invention there can be obtained a thin silver-alloy film which is uniform in both thickness distribution and composition distribution and which can exhibit stable characteristics.

### Example 4

Using silver alloy materials of the compositions shown in Table 4, targets were produced by various methods shown in the same table and then were measured for crystal orientation strength in the same manner as in Example 1, further, there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength and the second highest crystal orientation strength (X_{b}) at the measurement positions.

The targets were further checked for metal structure in the same way as in Examples 1 and 2.

Using the targets, thin films were formed in the same manner as in Example 1 and were checked for thickness distribution and composition distribution.

In this Example, the evaluation of film thickness distribution was made by measuring film thicknesses at five positions successively from an end of an arbitrary central line of each thin film to determine a ratio between a minimum film thickness and a maximum film thickness (minimum film thickness/maximum film thickness), and when the ratio was 0.90 or higher, it was determined that the film thickness was substantially uniform. As to the composition distribution, it was determined in the following manner. In the case of a binary silver alloy comprising silver and one alloy element, contents of the alloy component were determined successively at five positions from an end of an arbitrary central line of a thin film and the composition distribution was evaluated in terms of (minimum content value/maximum content value) of the alloy element. In the case of a ternary silver alloy comprising silver and two alloy elements, the composition distribution was evaluated in terms of (minimum content value/maximum content value) of the alloy element exhibiting a minimum value of (minimum content value/maximum content value) out of the two alloy elements. Then, when the ratio is 0.90 or higher, it was determined that the composition ratio was substantially uniform. The results of these measurements are shown in Table 5.

TABLE 4

| | | | | Cold | |
|---|---|---|---|---|---|
| Run | | | | Working | Heat |
| No. | Composition (at %) | Ingot Shape | Hot Working* | Ratio (%) | Treatment |
| 1 | Ag—0.9% Cu | Plate-like | — | 50 | 520° C. × 2 h |
| 2 | Ag—0.4% Cu—1.0% Au | Cylindrical | Forging (700° C., working ratio 35%) | 40 | 550° C. × 1 h |
| 3 | Ag—0.5% Cu—0.5% Au | Plate-like | — | 70 | 550° C. × 1 h |
| 4 | Ag—0.4% Zn—0.6% Cu | Cylindrical | Forging (600° C., working ratio 30%) | 50 | 550° C. × 1 h |
| 5 | Ag—0.8% Nd—1.0% Cu | Plate-like | — | 55 | 550° C. × 1 h |
| 6 | Ag—0.5% Nd | Cylindrical | Forging (700° C., working ratio 30%) | 50 | 550° C. × 2 h |
| 7 | Ag—0.3% Y—0.6% Cu | Plate-like | Forging (650° C., working ratio 25%) | 60 | 550° C. × 1 h |
| 8 | Ag—0.4% Cu—0.6% Au | Cylindrical | Forging (700° C., working ratio 30%) | — | — |
| | | | →Rolling (700° C., working ratio | | |
| | | | 50%) | | |
| 9 | Ag—0.8% Nd—1.0% Cu | Plate-like | — | 25 | 550° C. × 1 h |
| 10 | Ag—0.5% Nd—0.5% Zn | Cylindrical | Forging (650° C., working ratio 60%) | — | 600° C. × 1 h |

*The rolling temperature represents a rolling start temperature

TABLE 5

| | | | Orientation | | | | | | Film | | |
|---|---|---|---|---|---|---|---|---|---|---|---|
| | | Orientation | exhibiting | Variations | | | | | Thickness | | |
| | | exhibiting | the second | in crystal | | | | | Distribution | Composition Distribution | |
| | | the highest | highest | orientation | Crystal Grain | | | | (Minimum | | (Minimum |
| | | crystal | crystal | strength | Size. | | Compounds | | thickness/ | | value/ |
| Run | | orientation | orientation | ratio | Average | Max. | Average | Max. | Maximum | Component to | Maximum |
| No. | Composition (at %) | strength | strength | (%) | μm | μm | μm | μm | thickness) | be measured | value) |
| 1 | Ag—0.9% Cu | (111) at | (110) at | 14 | 85 | 170 | — | | 0.90 | Cu | 0.91 |
| | | all the four | three | | | | | | | | |
| | | positions | positions | | | | | | | | |
| | | | (100) at | | | | | | | | |
| | | | one | | | | | | | | |
| | | | position | | | | | | | | |
| 2 | Ag—0.4% Cu—1.0% Au | (111) at | (110) at | 10 | 95 | 177 | — | | 0.92 | Cu | 0.91 |
| | | all the four | all the four | | | | | | | | |
| | | positions | positions | | | | | | | | |
| 3 | Ag—0.5% Cu—0.5% Au | (111) at | (110) at | 8 | 32 | 59 | — | | 0.96 | Cu | 0.92 |
| | | all the four | all the four | | | | | | | | |
| | | positions | positions | | | | | | | | |
| 4 | Ag—0.4% Zn—0.6% Cu | (111) at | (110) at | 9 | 56 | 98 | — | | 0.95 | Cu | 0.90 |
| | | all the four | all the four | | | | | | | | |
| | | positions | positions | | | | | | | | |
| 5 | Ag—0.8% Nd—1.0% Cu | (111) at | (110) at | 8 | 39 | 60 | 33 | 54 | 0.96 | Nd | 0.90 |
| | | all the four | all the four | | | | | | | | |
| | | positions | positions | | | | | | | | |
| 6 | Ag—0.5% Nd | (111) at | (110) at | 12 | 65 | 111 | 31 | 52 | 0.93 | Nd | 0.90 |
| | | all the four | all the four | | | | | | | | |
| | | positions | positions | | | | | | | | |
| 7 | Ag—0.3% Y—0.6% Cu | (111) at | (110) at | 11 | 43 | 74 | 29 | 51 | 0.91 | Y | 0.91 |
| | | all the four | all the four | | | | | | | | |
| | | positions | positions | | | | | | | | |
| 8 | Ag—0.4% Cu—0.6% Au | (111) at | (110) at | 25 | 169 | 303 | — | | 0.70 | Cu | 0.81 |
| | | all the four | all the four | | | | | | | | |
| | | positions | positions | | | | | | | | |
| 9 | Ag—0.8% Nd—1.0% Cu | (111) at | (110) at | 23 | 117 | 222 | 37 | 68 | 0.75 | Nd | 0.79 |
| | | all the four | three | | | | | | | | |
| | | positions | positions | | | | | | | | |
| | | | (100) at | | | | | | | | |
| | | | one | | | | | | | | |
| | | | position | | | | | | | | |
| 10 | Ag—0.5% Nd—0.5% Zn | (110) at | (110) at | 30* | 175 | 355 | 30 | 50 | 0.67 | Nd | 0.85 |
| | | three | three | | | | | | | | |
| | | positions | positions | | | | | | | | |
| | | (111) at | (111) at | | | | | | | | |
| | | one | one | | | | | | | | |
| | | position | position | | | | | | | | |

*Variations in orientation (111) exhibiting the highest crystal orientation strength at three positions

The following can be estimated from Tables 4 and 5. No. in the following description represents Run No. in Tables 4 and 5.

No. 1 to No. 7 targets satisfy the conditions defined in the present invention, so it is seen that in case of using them in forming thin films by the sputtering method, there were obtained thin films uniform in both thickness distribution and composition distribution and capable of exhibiting such stable characteristics as high reflectivity and excellent thermal conductivity. It is seen that in the case of a target wherein the orientation exhibiting the highest crystal orientation strength (Xₐ) is the same at the four measurement positions and the orientation exhibiting the second highest crystal orientation strength (X_{b}) is also the same at the four measurement positions, there is obtained a thin film more uniform in film thickness distribution.

In contrast therewith, as to No. 8 to No. 10, they do not satisfy the conditions defined in the present invention, the orientation exhibiting the highest crystal orientation strength (Xₐ) is not the same at all of the measurement positions, variations in strength ratio (X_{b}/Xₐ) between the highest crystal orientation strength (Xₐ) and the second highest crystal orientation strength (X_{b}) are large, and the crystal grain size is also large, so that all of thin films obtained are not uniform in thickness distribution and composition distribution and the exhibition of stable characteristics referred to above cannot be expected.

### Example 5

Silver alloy material: Ag-0.4 at % Nd-0.5 at % Cu

Manufacturing Method:

\textcircled{1} Example of the Present Invention

Induction melting (Ar atmosphere)→casting (into a plate shape with use of a mold)→hot rolling (rolling start temperature 650° C., working ratio 70%)→cold rolling (working ratio 50%)→heat treatment (500° C.×2 hours)→machining (a disc shape 200 mm dia. by 6 mm thick)

\textcircled{1} Comparative Example

Induction melting (Ar atmosphere)→casting (into a plate shape with use of a mold)→hot rolling (rolling start temperature 700° C., working ratio 40%)→heat treatment (500° C.×1 hour)→machining (a disc shape 200 mm dia. by 6 mm thick)

The resulting targets were measured for crystal orientation strength in the same way as in Example 1 and there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}) at the measurement positions. Further, the targets were checked for metal structure in the same manner as in Example 1. The results obtained are shown in Table 6.

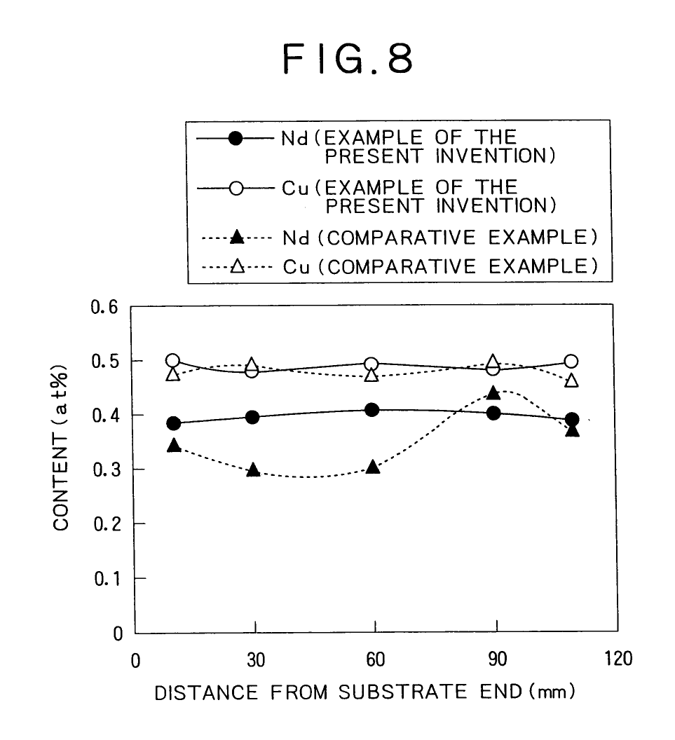

Using the targets and in the same manner as in Example 1 there were formed thin films. The thin films were then evaluated for thickness distribution and composition distribution in the same way as in Example 1. Thickness distributions and composition distributions of the thin films are shown in Table 6 below and FIG. 8, respectively.

TABLE 6

| | | Orientation | | | | | | | | | | |
|---|---|---|---|---|---|---|---|---|---|---|---|---|
| | Orientation | exhibiting the | Variations in | | | | | | | | | |
| | exhibiting the | second | crystal | | | | | | | | | |
| | highest | highest | orientation | Crystal Grain | | | | | | | | |
| | crystal | crystal | strength | Size | | Compounds | | Film Thickness Distribution (Å) | | | | |
| | orientation | orientation | ratio | Average | Max. | Average | Max. | Distance from substrate end (mm) | | | | |
| | strength | strength | (%) | μm | μm | μm | μm | 10 | 30 | 60 | 90 | 110 |
| Example of | (111) at all | (220) at all | 12 | 20 | 50 | 18 | 35 | 970 | 1020 | 1020 | 1030 | 980 |
| the present | the four | the four | | | | | | | | | | |
| invention | positions | positions | | | | | | | | | | |
| Comparative | (111) at three | (220) at | 25* | 100 | 300 | 44 | 80 | 940 | 1100 | 920 | 990 | 900 |
| Example | positions | three | | | | | | | | | | |
| | (220) at one | positions | | | | | | | | | | |
| | position | (111) at one | | | | | | | | | | |
| | | position | | | | | | | | | | |

*Variations in orientation (111) exhibiting the highest crystal orientation strength at three positions

From these results it is seen that if a target whose metal structure satisfies the conditions defined in the present invention is used in sputtering, there can be obtained a thin silver-alloy film having a uniform thickness distribution within the thin film surface and capable of exhibiting stable characteristics. Reference to FIG. 8 shows that the composition distributions of the targets obtained according to the present invention are more uniform than in the Comparative Example.

### Example 6

Silver alloy material: Ag-0.8 at % Y-1.0 at % Au

Manufacturing Method:

\textcircled{1} Example of the Present Invention

Vacuum induction melting→casting (produce a cylindrical ingot with use of a mold)→hot casting (700° C., working ratio 35%)→hot working (rolling start temperature 700° C., working ratio 35%)→cold rolling (working ratio 50%)→heat treatment (550° C.×1.5 hours)→machining (into the same shape as in Example 1)

\textcircled{2} Comparative Example

Vacuum induction melting→casting (produce a cylindrical ingot with use of a mold)→hot forging (650° C., working ratio 40%, into a cylindrical shape)→heat treatment (400° C.×1 hour)→machining (into the same shape as in Example 1)

The resulting targets were determined for crystal orientation strength in the same way as in Example 1 and there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}) at the measurement positions. Further, the targets were checked for metal structure in the same manner as in Examples 1 and 2. The results obtained are shown in Table 7.

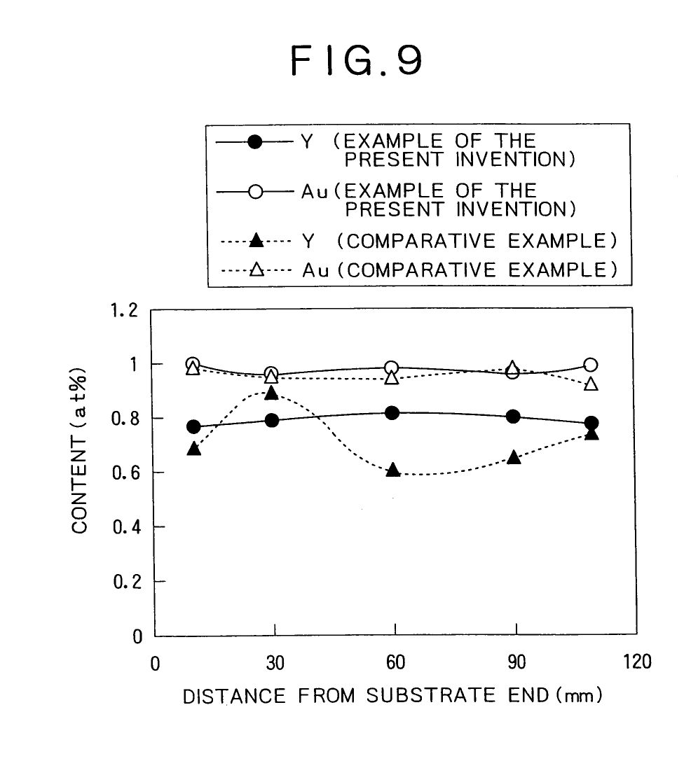

Using the targets and in the same manner as in Example 1 thin films were formed and then evaluated for thickness distribution and composition distribution. Thickness distributions and composition distributions of the thin films are shown in Table 7 and FIG. 9, respectively.

TABLE 7

| | | Orientation | | | | | | | | | | |
|---|---|---|---|---|---|---|---|---|---|---|---|---|
| | Orientation | exhibiting the | Variations in | | | | | | | | | |
| | exhibiting the | second | crystal | | | | | | | | | |
| | highest | highest | orientation | Crystal Grain | | | | | | | | |
| | crystal | crystal | strength | Size | | Compounds | | Film Thickness Distribution (Å) | | | | |
| | orientation | orientation | ratio | Average | Max. | Average | Max. | Distance from substrate end (mm) | | | | |
| | strength | strength | (%) | μm | μm | μm | μm | 10 | 30 | 60 | 90 | 110 |
| Example of | (111) at all | (220) at all | 14 | 25 | 70 | 25 | 45 | 980 | 1040 | 1010 | 1030 | 970 |
| the present | the four | the four | | | | | | | | | | |
| invention | positions | positions | | | | | | | | | | |
| Comparative | (111) at three | (220) at | 27* | 90 | 250 | 35 | 75 | 950 | 1100 | 900 | 910 | 1050 |
| Example | positions | three | | | | | | | | | | |
| | (220) at one | positions | | | | | | | | | | |
| | position | (111) at one | | | | | | | | | | |
| | | position | | | | | | | | | | |

*Variations in orientation (111) exhibiting the highest crystal orientation strength at three positions

From these results it is seen that by sputtering a target whose metal structure satisfies the conditions defined in the present invention, there is obtained a thin silver-alloy film uniform in both thickness distribution and composition distribution and capable of exhibiting stable characteristics.

### Example 7

Silver alloy material: Ag-0.5 at % Ti

Manufacturing Method:

\textcircled{1} Example of the Present Invention

Vacuum induction melting→casting (produce a cylindrical ingot with use of a mold)→hot forging (700° C., working ration 25%)→hot rolling (rolling start temperature 650° C., working ratio 40%)→cold rolling (working ratio 50%)→heat treatment (550° C.×1 hour)→machining (into the same shape as in Example 1)

\textcircled{1} Comparative Example

Vacuum induction melting→casting (produce a cylindrical ingot with use of a mold)→heat treatment (500° C.×1 hour)→machining (into the same shape as in Example 1)

Targets obtained in the same way as in Example 1 were measured for crystal orientation strength and there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}) at the measurement positions. Further, the targets were checked for metal structure in the same manner as in Examples 1 and 2. The results obtained are shown in Table 8.

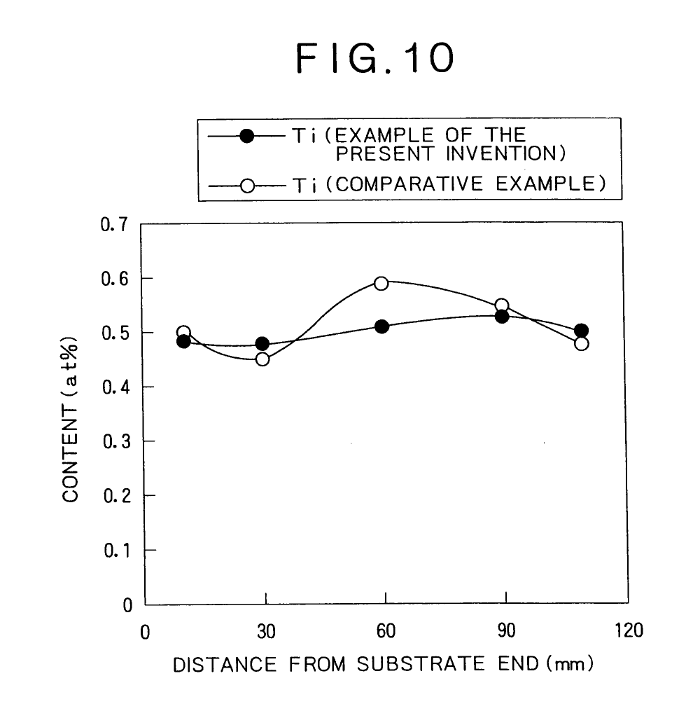

Using the targets and in the same way as in Example 1 thin films were formed and then determined for thickness distribution and composition distribution. Thickness distributions and composition distributions of the thin films are shown in Table 8 below and FIG. 10, respectively.

TABLE 8

| | | Orientation | | | | | | | | | | |
|---|---|---|---|---|---|---|---|---|---|---|---|---|
| | Orientation | exhibiting the | Variations in | | | | | | | | | |
| | exhibiting the | second | crystal | | | | | | | | | |
| | highest | highest | orientation | Crystal Grain | | | | | | | | |
| | crystal | crystal | strength | Size | | Compounds | | Film Thickness Distribution (Å) | | | | |
| | orientation | orientation | ratio | Average | Max. | Average | Max. | Distance from substrate end (mm) | | | | |
| | strength | strength | (%) | μm | μm | μm | μm | 10 | 30 | 60 | 90 | 110 |
| Example of | (111) at all | (220) at all | 12 | 20 | 50 | 15 | 30 | 985 | 1050 | 1005 | 1025 | 975 |
| the present | the four | the four | | | | | | | | | | |
| invention | positions | positions | | | | | | | | | | |
| Comparative | (111) at two | (220) at | — | 200 | 600 | 50 | 130 | 955 | 1110 | 895 | 905 | 1055 |
| Example | positions | three | | | | | | | | | | |
| | (220) at two | positions | | | | | | | | | | |
| | positions | (111) at one | | | | | | | | | | |
| | | position | | | | | | | | | | |

From these results it is seen that by sputtering a target whose metal structure satisfies the conditions defined in the present invention, there can be obtained a thin silver-alloy film uniform in both thickness distribution and composition distribution and capable of exhibiting stable characteristics.

### Example 8

Next, using silver alloy materials of the compositions shown in Table 9, targets were produced by such various methods as shown in Table 9. Then, in the same manner as in Example 1, with respect to the targets thus produced, there were determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}) at the measurement positions. Further, the targets were checked for metal structure in the same manner as in Examples 1 and 2. The results obtained are shown in Table 10.

Using the targets and in the same way as in Example 1 there were formed thin films, which were then evaluated for thickness distribution and composition distribution in the same manner as in Example 4.

TABLE 9

| | | Casting | | | | | |
|---|---|---|---|---|---|---|---|
| | | | | Cooling | | Cold | |
| Run | | | | Speed | | Working | Heat |
| No. | Composition (at %) | Mold Material | Ingot Shape | (° C./s) | Hot Working* | Ratio (%) | Treatment |
| 1 | Ag—0.5% Nd | Copper | Plate-like | 2 | Rolling (700° C., working ratio 50%) | 40 | 550° C. × 1 h |
| | | | 50 mm | | | | |
| 2 | Ag—0.4% Nd—0.5% Au | Graphite | Cylindrical | 1 | Forging (700° C., working ratio 35%) | 55 | 550° C. × 1 h |
| | | | 150 mm dia. | | → Rolling (700° C., working ratio 35%) | | |
| 3 | Ag—0.8% Nd—1.0% Cu | Cast iron | Cylindrical | 0.8 | Forging (700° C., working ratio 40%) | 65 | 600° C. × 1 h |
| | | | 200 mm dia. | | → Rolling (700° C., working ratio 45%) | | |
| 4 | Ag—0.4% Nd—0.6% Cu | Graphite | Plate-like | 3 | Rolling (700° C., working ratio 50%) | 40 | 550° C. × 1 h |
| | | | 30 mm | | | | |
| 5 | Ag—0.8Nd—1.0% Au | Copper | Plate-like | 2 | Rolling (600° C., working ratio 60%) | 40 | 500° C. × 2 h |
| | | | 50 mm | | | | |
| 6 | Ag—0.5% Y—0.5% Zn | Copper | Plate-like | 2.5 | Forging (700° C., working ratio 20%) | 55 | 550° C. × 1 h |
| | | | 40 mm | | → Rolling (650° C., working ratio 35%) | | |
| 7 | Ag—0.8% Y—1.1% Cu | Graphite | Cylindrical | 1 | Rolling (650° C., working ratio 50%) | 50 | 550° C. × 1.5 h |
| | | | 150 mm dia. | | | | |
| 8 | Ag—0.8% Nd—1.0% Cu | Graphite | Plate-like | 1.5 | — | 25 | 550° C. × 1 h |
| | | | 50 mm | | | | |
| 9 | Ag—0.5% Y—0.5% Zn | Cast iron | Plate-like | 0.9 | Rolling (650° C., working ratio 45%) | — | 650° C. × 1 h |
| | | | 80 mm dia. | | | | |

*The rolling temperature represents a rolling start temperature

TABLE 10

| | | | Orientation | | | | | | Film | | |
|---|---|---|---|---|---|---|---|---|---|---|---|
| | | Orientation | exhibiting | Variations | | | | | Thickness | | |
| | | exhibiting | the second | in crystal | | | | | Distribution | Composition Distribution | |
| | | the highest | highest | orientation | Crystal Grain | | | | (Minimum | | (Minimum |
| | | crystal | crystal | strength | Size | | Compounds | | thickness/ | Component | value/ |
| Run | | orientation | orientation | ratio | Average | Max. | Average | Max. | Maximum | to be | Maximum |
| No. | Composition (at %) | strength | strength | (%) | μm | μm | μm | μm | thickness) | measured | value) |
| 1 | Ag—0.5% Nd | (111) at | (220) at | 14 | 40 | 120 | 24 | 40 | 0.93 | Nd | 0.91 |
| | | all the four | all the four | | | | | | | | |
| | | positions | positions | | | | | | | | |
| 2 | Ag—0.4% Nd—0.5% Au | (111) at | (220) at | 11 | 45 | 115 | 23 | 46 | 0.92 | Nd | 0.95 |
| | | all the four | all the four | | | | | | | | |
| | | positions | positions | | | | | | | | |
| 3 | Ag—0.8% Nd—1.0% Cu | (111) at | (220) at | 9 | 85 | 180 | 25 | 47 | 0.90 | Nd | 0.93 |
| | | all the four | all the four | | | | | | | | |
| | | positions | positions | | | | | | | | |
| 4 | Ag—0.4% Nd—0.6% Cu | (111) at | (220) at | 16 | 50 | 130 | 21 | 42 | 0.92 | Nd | 0.92 |
| | | all the four | three | | | | | | | | |
| | | positions | positions | | | | | | | | |
| | | | (111) at | | | | | | | | |
| | | | one | | | | | | | | |
| | | | position | | | | | | | | |
| 5 | Ag—0.8% Nd—1.0% Au | (111) at | (220) at | 14 | 35 | 95 | 19 | 36 | 0.95 | Nd | 0.96 |
| | | all the four | all the four | | | | | | | | |
| | | positions | positions | | | | | | | | |
| 6 | Ag—0.5% Y—0.5% Zn | (111) at | (220) at | 10 | 45 | 90 | 20 | 40 | 0.94 | Y | 0.94 |
| | | all the four | all the four | | | | | | | | |
| | | positions | positions | | | | | | | | |
| 7 | Ag—0.8% Y—1.1% Cu | (111) at | (220) at | 13 | 65 | 150 | 24 | 44 | 0.91 | Y | 0.91 |
| | | all the four | all the four | | | | | | | | |
| | | positions | positions | | | | | | | | |
| 8 | Ag—0.8% Nd—1.0% Cu | (111) at | (220) at | 25* | 120 | 260 | 55 | 105 | 0.70 | Nd | 0.80 |
| | | three | three | | | | | | | | |
| | | positions | positions | | | | | | | | |
| | | (220) at | (111) at | | | | | | | | |
| | | one | one | | | | | | | | |
| | | position | position | | | | | | | | |
| 9 | Ag—0.5% Y—0.5% Zn | (111) at | (111) at | — | 120 | 350 | 80 | 130 | 0.68 | Y | 0.70 |
| | | two | two | | | | | | | | |
| | | position | position | | | | | | | | |
| | | (220) at | (220) at | | | | | | | | |
| | | two | two | | | | | | | | |
| | | position | position | | | | | | | | |

*Variations in orientation (111) exhibiting the highest crystal orientation strength at three positions

The following can be estimated from Tables 9 and 10. No. in the following description represents Run No. in Tables 9 and 10.

No. 1 to No. 7 targets satisfy the conditions defined in the present invention and therefore it is seen that in case of using them in forming thin films by the sputtering method, there are obtained thin films uniform in both thickness distribution and composition distribution and capable of exhibiting stable characteristics such as high reflectivity and high thermal conductivity. In contrast therewith, No. 8 and No. 9 do not satisfy the conditions defined in the present invention and all of thin films obtained using them are not uniform in thickness distribution and composition distribution and it is impossible to expect their exhibition of stable characteristics referred to above.

### Example 9

Further, using silver alloy materials of the compositions shown in Table 11, the present inventors produced targets by such various methods as shown in Table 11 and, with respect to the resulting targets, determined orientation exhibiting the highest crystal orientation strength (Xₐ), orientation exhibiting the second highest crystal orientation strength (X_{b}), and variations in strength ratio (X_{b}/Xₐ) between the highest crystal orientation strength (Xₐ) and the second highest crystal orientation strength (X_{b}). The targets were then checked for metal structure in the same way as in Examples 1 and 2. The results obtained are shown in Table 12.

Using the targets and in the same manner as in Example 1 there were formed thin films, which were then evaluated for thickness distribution and composition distribution in the same way as in Example 4.

TABLE 11

| | | Casting | | | | | |
|---|---|---|---|---|---|---|---|
| | | | | Cooling | | | |
| Run | | Mold | | Speed | | Cold | |
| No. | Composition (at %) | Material | Ingot Shape | (° C./s) | Hot Working | Working | Heat Treatment |
| 1 | Ag—0.8% Cu—1.0% Au | Graphite | Plate-like | 0.9 | — | Rolling 70% | 600° C. × 2.5 h |
| | | | 40 mm | | | | |
| 2 | Ag—0.6% Nd—0.9% Cu | Graphite | Cylindrical | 0.8 | 650° C. forging 20% | Rolling 60% | 600° C. × 2 h |
| | | | 90 mm dia. | | | | |
| 3 | Ag—0.8% Cu—1.0% Au | Steel | Plate-like | 0.9 | — | Rolling 70% | 550° C. × 0.75 h |
| | | | 40 mm | | | | |
| 4 | Ag—0.6% Nd—0.9% Cu | Graphite | Cylindrical | 0.5 | 700° C. forging 30% | Rolling 70% | 550° C. × 1.25 h |
| | | | 150 mm dia. | | | | |
| 5 | Ag—0.6Nd—0.9% Cu | Graphite | Cylindrical | 0.5 | 700° C. forging 30% → | Rolling 55% | 550° C. × 1.25 h |
| | | | 150 mm dia. | | 700° C. rolling 30% (total 60%) | | |
| 6 | Ag—0.8% Cu—1.0% Au | Graphite | Plate-like | 0.9 | 700° C. rolling 65% | Rolling 10% | 650° C. × 1 h |
| | | | 40 mm | | | | |
| 7 | Ag—0.6% Nd—0.9% Cu | Sand mold | Cylindrical | 0.2 | 700° C. forging 35% | Rolling 25% | 550° C. × 1 h |
| | | (chromite) | 90 mm dia. | | | | |

TABLE 12

| | | | Orientation | | | | | | Film | | |
|---|---|---|---|---|---|---|---|---|---|---|---|
| | | Orientation | exhibiting | Variations | | | | | Thickness | | |
| | | exhibiting | the second | in crystal | | | | | Distribution | Composition Distribution | |
| | | the highest | highest | orientation | Crystal Grain | | | | (Minimum | | (Minimum |
| | | crystal | crystal | strength | Size | | Compounds | | thickness/ | | value/ |
| Run | | orientation | orientation | ratio | Average | Max. | Average | Max. | Maximum | Component to | Maximum |
| No. | Composition (at %) | strength | strength | (%) | μm | μm | μm | μm | thickness) | be measured | value) |
| 1 | Ag—0.8% Cu—1.0% A | (111) at | (220) at | 10 | 105 | 206 | — | | 0.90 | Cu | 0.91 |
| | | all the four | all the four | | | | | | | | |
| | | positions | positions | | | | | | | | |
| 2 | Ag—0.6% Nd—0.9% C | (111) at | (220) at | 12 | 100 | 205 | 37 | 53 | 0.92 | Nd | 0.90 |
| | | all the four | all the four | | | | | | | | |
| | | positions | positions | | | | | | | | |
| 3 | Ag—0.8% Cu—1.0% A | (111) at | (220) at | 9 | 45 | 88 | — | | 0.95 | Cu | 0.96 |
| | | all the four | all the four | | | | | | | | |
| | | positions | positions | | | | | | | | |
| 4 | Ag—0.6% Nd—0.9% C | (111) at | (220) at | 8 | 35 | 72 | 34 | 51 | 0.96 | Nd | 0.91 |
| | | all the four | all the four | | | | | | | | |
| | | positions | positions | | | | | | | | |
| 5 | Ag—0.6% Nd—0.9% C | (111) at | (220) at | 11 | 56 | 103 | 23 | 36 | 0.94 | Nd | 0.95 |
| | | all the four | all the four | | | | | | | | |
| | | positions | positions | | | | | | | | |
| 6 | Ag—0.8% Cu—1.0% A | (111) at | (220) at | 30* | 124 | 350 | — | | 0.68 | Cu | 0.88 |
| | | three | three | | | | | | | | |
| | | positions | positions | | | | | | | | |
| | | (110) at | (111) at | | | | | | | | |
| | | one | one | | | | | | | | |
| | | position | position | | | | | | | | |
| 7 | Ag—0.6% Nd—0.9% C | (111) at | (220) at | 24 | 122 | 241 | 55 | 94 | 0.78 | Nd | 0.70 |
| | | all the four | three | | | | | | | | |
| | | positions | positions | | | | | | | | |
| | | | (111) at | | | | | | | | |
| | | | one | | | | | | | | |
| | | | position | | | | | | | | |

*Variations in orientation (111) exhibiting the highest crystal orientation strength at three positions

The following can be estimated from Tables 11 and 12. No. in the following description represent Run No. in Tables 11 and 12.

No. 1 to No. 5 targets satisfy the conditions defined in the present invention and therefore when they were used in forming thin films by the sputtering method, there were obtained thin films uniform in both thickness distribution and composition distribution and capable of exhibiting such stable characteristics as high reflectivity and high thermal conductivity.

Particularly, it is seen that if not only crystal orientation but also the crystal grain size of target and silver-alloy compounds present in grain boundaries and crystal grains are controlled to within the preferred ranges in the present invention, there can be formed thin films more uniform in thickness distribution and composition distribution.

In contrast therewith, No. 6 and No. 7 do not satisfy the conditions defined in the present invention and all of the resulting thin films are not uniform in thickness distribution and composition distribution and their exhibition of the foregoing characteristics cannot be expected.

### INDUSTRIAL APPLICABILITY

The present invention is constructed as above and provides a target which is useful in forming a thin silver-alloy film uniform in both thickness distribution and composition distribution by the sputtering method. A thin silver-alloy film formed by the sputtering method using such a target exhibits such stable characteristics as high reflectivity and high thermal conductivity and when it is used, for example, as a reflective film in an optical recording medium such as a semi-transmissive reflective film in DVD of a one-side two-layer structure or a reflective film in a next-generation optical recording medium or as an electrode and reflective film in a reflection type liquid crystal display, it is possible to further improve the performance of such reflective films.

What we claim is:

1. A silver alloy sputtering target wherein when crystal orientation strengths are determined at four arbitrary positions by an X-ray diffraction method, the orientation which exhibits the highest crystal orientation strength (Xₐ) is the same at the four measurement positions, and variations in strength ratio (X_{b}/Xₐ) between the highest crystal orientation strength (Xₐ) and the second highest crystal orientation strength (X_{b}) at the four measurement positions are 20% or less, and wherein said silver alloy consists of Ag and at least one rare earth element, wherein said rare earth element does not exceed 1 at %, and, optionally, at least one element selected from the group consisting of Cu, Au, Ti, and Zn.

2. The silver alloy sputtering target according to claim 1, wherein the orientation which exhibits the second highest crystal orientation strength (X_{b}) is the same at the four measurement positions.

3. The silver alloy sputtering target according to claim 1, wherein an average crystal grain size is 100 μm or less and a maximum crystal grain size is 200 μm or less.

4. The silver alloy sputtering target according to claim 1, wherein equivalent area diameters of silver-alloy compounds present in grain boundaries and/or crystal grains are 30 μm or less on the average, and a maximum value of the equivalent area diameters is 50 μm or less.

5. A method for producing the silver alloy sputtering target described in claim 1, comprising cold working or warm working at a working ratio of 30% to 70% and thereafter heat treating under the conditions of a holding temperature of 500° to 600° C. and a holding time of 0.75 to 3 hours.

6. The method according to claim 5, wherein the heat treatment is performed under the conditions of a holding temperature of 500° to 600° C. and a holding time falling under the range of the following expression (4):
(−0.005×T+3.5)≦t≦(−0.01×T+8) (4)
where T stands for a holding temperature (° C.) and t stands for a holding time (hour).

7. The silver alloy sputtering target according to claim 1, wherein said rare earth element is present in an amount not to exceed 1.0 at %.

8. The silver alloy sputtering target according to claim 1, wherein said rare earth element is Nd.

9. The silver alloy sputtering target according to claim 8, wherein Nd is present in an amount not to exceed 1.0 at %.

10. The silver alloy sputtering target according to claim 1, wherein said rare earth element is Y.

11. The silver alloy sputtering target according to claim 10, wherein Y is present in an amount not to exceed 1.0 at %.

12. The silver alloy sputtering target according to claim 1, wherein said silver alloy further comprises Ti.

13. The silver alloy sputtering target according to claim 1, wherein said silver alloy further comprises Zn.

14. The silver alloy sputtering target according to claim 1, wherein said silver alloy further comprises Cu.

15. The silver alloy sputtering target according to claim 14, wherein Cu is present in an amount not to exceed 2.0 at %.

16. The silver alloy sputtering target according to claim 1, wherein said silver alloy further comprises Au.

17. The silver alloy sputtering target according to claim 16, wherein Au is present in an amount not to exceed 2.0 at %.
